(19) United States
(12) Patent Application Publication
(10) Pub. No.: US 2026/0045296 A1
(43) Pub. Date: Feb. 12, 2026

(54) COMPACT IN-MEMORY COMPUTER ARCHITECTURE

(71) Applicant: SYNTHARA AG, Zürich (CH)

(72) Inventor: Avinash GUTTA, Bengaluru (IN)

(21) Appl. No.: 19/100,759

(22) PCT Filed: Aug. 5, 2022
(86) PCT No.: PCT/EP2022/072166

§ 371 Date: Feb. 3, 2025

(51) Int. Cl. G11C 11/419

(52) U.S. Cl. CPC G11C 11/419

(57) ABSTRACT

A compact in-memory computer architecture includes memory components arranged in rows and columns, bit lines each connecting a row of memory components, and word lines each connecting a column of memory components. Each memory component has a bit cell and a compute engine connected to the bit cell. The bit cell is operable to store a bit and the compute engine is operable to process the bit. Each bit line connects a respective row of memory components and is operable to provide a bit to each memory component in the row of memory components. Each word line connects a respective column of memory components and is operable to enable each memory component in the column of memory components to write a bit into each memory component in the column of memory components.

### TECHNICAL FIELD

The present disclosure relates generally to distributed digital memory and computing element architectures, devices, and methods that facilitate matrix multiplication.

### BACKGROUND

Matrix multiplication is an important operation in many mathematical computations. For example, linear algebra can employ matrix multiplication to solve systems of linear equations such as differential equations. Such mathematical computations are applied, for example, in pattern matching, artificial intelligence, analytic geometry, engineering, physics, natural sciences, computer science, computer animation, and economics.

Matrix multiplication is typically performed in digital computers executing stored programs. The programs describe the operations to be performed and hardware in the computer, for example digital multipliers and adders, perform the operations. The data (matrices) operated upon are stored in digital memories, for example static random access memory (SRAM) or dynamic random access memory (DRAM) accessed through a memory-and-address bus. The number of bits retrieved at a time in parallel is limited by the bus bit width and corresponds to the number of bits in the memory enabled by an address provided to the memory. In some computing systems, specially designed hardware can accelerate the rate of computation.

In some applications, real-time processing is necessary to provide useful output in useful amounts of time, especially for safety-critical tasks. However, access to data stored in memory is an intrinsic limitation in conventional digital computing systems. Moreover, applications in portable devices have only limited power available.

In general, calculations requiring large matrices and high data rates can take longer to solve and use more power than desired. There is a need therefore, for computing logic and memory architectures that can perform matrix multiplication at higher data rates and with less power.

### SUMMARY

Embodiments of the present disclosure can provide, inter alia, compact in-memory computer architectures suitable for performing matrix multiplication with improved efficiency and speed in a compact design that reduces the amount of physical hardware (e.g., semiconductor wafer area) required. By limiting the area, costs are reduced, and performance increased. The compact in-memory architectures can provide massively parallel processing of large numbers of values, for example performing many matrix multiplication operations at the same time.

According to embodiments of the present disclosure, a compact in-memory computer architecture includes memory components arranged in rows and columns, bit lines each connecting a row of memory components, and word lines each connecting a column of memory components. Each memory component has a bit cell or multiple bit cells and a compute engine connected to the bit cell. The bit cell is operable to store a bit and the compute engine is operable to process the bit. Each bit line connects a respective row of memory components and is operable to provide a bit to each memory component in the row of memory components. Each word line connects a respective column of memory components and is operable to enable each memory component in the column of memory components to write a bit into each memory component in the column of memory components. The rows and columns of memory components can form an array of memory components connected in a matrix with the bit lines (e.g., in a horizontal row direction) and the word lines (e.g., in a vertical column direction). (Horizontal and vertical are arbitrary orthogonal designations.) In some embodiments, the compute engine is operable to process the bit (or bits) in a storage element in the memory component in combination with a bit (or bits) accessed externally to the compact in-memory computer architecture.

In some embodiments, each memory component is connected to an external bit line through a memory select (MEMSEL) switch. The memory-select switch can isolate the bit cell (and compute engine) from external devices connected to the bit line. An external device is a device spatially and physically external to the memory components connected to the memory components. The externally accessible bit line external to the memory component is an external bit line and the bit line internal to the memory component that is isolated with the memory-select switch from the external devices is an internal bit line. Collectively, the internal and external bit lines are bit lines. When closed, the memory-select switch connects the bit cell to any external devices (such as a controller) through the external bit line. When the memory-select switch is open, the bit cell and internal bit line are electrically isolated from any external devices (such as a controller) connected through the external bit line. In some embodiments, the memory-select switch of each memory component is controlled in common, for example electrically connected in common to a common control signal so that all of the memory-select switches (for example in a row, column, or all of the memory components in the array) are operated together with the common control signal.

According to some embodiments of the present disclosure, each memory component comprises multiple bit cells connected to the compute engine and each bit cell of the multiple bit cells is connected to a common bit line and to a different word line so that each compute engine can access the multiple bits stored in the multiple bit cells. The multiple bit cells in a memory component can store a single multi-bit value such as a byte, word, or long word.

In some embodiments, each bit cell in a memory component is connected directly to the compute engine of only that compute engine so that the compute engine can access all of the bits stored in the bit cells of a common memory component in parallel. In some such embodiments, the compute engine of a memory component can access the one or more bit cells of the memory component serially, for example one bit cell at a time or some group of bit cells less than all of the bit cells at a time. Each of the compute engines in an array of memory components can access the bit cell(s) in the memory component in parallel.

According to some embodiments, a controller controls the memory components in the array.

According to some embodiments, the memory components are disposed on a substrate and each memory component can be spatially disposed on or over a different portion of the substrate and is adjacent to another memory component. The compute engine of each memory component can be disposed spatially adjacent to the bit cell or bit cells of the memory component. At least one of the compute engines in the memory components can be spatially disposed between the bit cell of the memory component and the bit cell of the adjacent memory component so that bit cells (or groups of bit cells) and compute engines spatially alternate in at least one direction.

According to some embodiments of the present disclosure, each compute engine in a memory component is connected to the compute engine of an adjacent compute engine. In some embodiments, adjacent compute engines can communicate or transmit data (e.g., processed bits) from one compute engine to an adjacent compute engine. In some embodiments, adjacent compute engines can be connected together and can share data, for example average data found in the adjacent compute engines.

According to some embodiments of the present disclosure, in at least some of the memory components, the compute engine is connected to the bit cell with the corresponding bit line (e.g., the internal bit line) so that the bit line on which bits are transmitted to a bit cell from an external source or external controller is also the bit line (e.g., the internal bit line) that connects the compute engine to the bit cell.

According to some embodiments, the compute engine comprises a bit multiplier for multiplying bits stored in the bit cells to calculate a product and a product storage circuit that is or comprises a capacitor for storing the product. In some embodiments the bit multiplier is a single-bit multiplier. In some embodiments, the bit multiplier is an iterative bit multiplier that effectively scales and accumulates bit products.

According to some embodiments of the present disclosure, a method of operating a compact in-memory computer architecture comprises using the controller to provide a bit on each bit line, using the controller to enable the word line of a column of memory components to store the bit into the bit cell of each memory component in the column of memory components, and using the compute engine of each memory component in the column of memory components to process the stored bit. Each memory component can be connected to a corresponding bit line through a memory select (MEMSEL) switch and methods of the present disclosure can comprise using the controller to turn the MEMSEL switch on before using the controller to provide the bit on each bit line and to turn the MEMSEL switch off after using the controller to provide the bit on each bit line before using the compute engine of each memory component in the column of memory components to process the stored bit.

Some embodiments of the present disclosure comprise serially multiplying multiple bits of a first multi-bit value by a bit of a second multi-bit value. Some embodiments of the present disclosure comprise multiplying multiple bits of a first multi-bit value by a bit of a second multi-bit value in parallel. Some embodiments of the present disclosure comprise multiplying all of the bits of a first multi-bit value by a bit of a second multi-bit value in parallel or serially. Some embodiments of the present disclosure comprise multiplying multiple bits of a first multi-bit value by multiple bits of a second multi-bit value in parallel or serially. Some embodiments of the present disclosure comprise multiplying all of the bits of a first multi-bit value by all of the bits of a second multi-bit value in parallel. In some embodiments, products of multiple bits of a first value and a single bit of a second value are scaled and accumulated. In some embodiments, bit products of a first multi-bit value and a second multi-bit value are accumulated, for example by averaging the bit products with parallel-connected capacitors in which the bit products are stored. In some embodiments, accumulated bit products are scaled and accumulated.

Some embodiments of the present disclosure comprise storing bit products in capacitors and summing the bit products by connecting the capacitors in parallel. Some embodiments of the present disclosure comprise iteratively summing and scaling bit products in an accumulating capacitor.

In some embodiments of the present disclosure, a multi-processor computer system comprises a compact in-memory computer comprising memory components, each memory component comprising a compute engine and a storage element for storing data, the compute engine operable to read and process data stored only in the storage element of the memory component; and a processor external to the compact in-memory computer connected to and operable to write data to each storage element in the compact in-memory computer. In some embodiments, the compact in-memory computer can be or can comprise a compact in-memory computer architecture. The compact in-memory computer can comprise an array of memory components in the compact in-memory computer architecture and can be a compact in-memory computer architecture. Each compute engine can be operable to process data stored in the storage element in response to an operate command. The storage element can comprise one or more bit cells. The processor can provide an operate command together with data as part of a storage element write operation that writes data into the storage elements of the memory components. The operate command can instruct the compute engine to perform an operation or not to perform an operation (e.g., a null operation).

In some embodiments, each memory component is directly connected to at least one other memory component to transmit and receive data directly to and from the other memory component. In some embodiments data is stored in capacitors. In some embodiments, capacitors in different memory components are connected together and data in the different memory components are averaged together.

In some embodiments, the storage elements are responsive to compact in-memory-computer addresses in a compact in-memory-computer address range and the processor is operable to write data to storage elements in memory components at the compact in-memory-computer addresses. In some embodiments, the processor has a processor address space, and the storage elements are memory mapped into the processor address space. In some embodiments, a processor memory can be connected to the processor, the processor is operable to write and read processor data to and from the processor memory, and the processor memory is memory mapped into the processor address space at a processor-memory address range distinct from the compact in-memory-computer address range. The processor memory can be operable to store processor instructions.

Each memory component can comprise one or more of a bit memory, a multi-bit memory, a single-bit multiplier, or an iterative multi-bit multiplier. The storage element in each memory component can comprise one or more of a bit memory or a multi-bit memory, for example a bit cell or a multi-bit cell. The compute engine in each memory component can comprise a single-bit multiplier or an iterative multi-bit multiplier.

Each compute engine can comprise a capacitive product storage circuit, a capacitive accumulator storage circuit, or both a product storage circuit and a capacitive accumulator storage circuit. The capacitive product storage circuits of two or more memory components can be connected together, for example the capacitive product storage circuits of pairs of adjacent memory components.

In some embodiments, the processor comprises a controller that controls the compact in-memory computer. The controller can receive analog data from the memory components, e.g., charges or voltages. The controller can convert the received analog data to digital data.

The controller can accumulate data received from one or more memory components. The controller can comprise a multiplexer or a demultiplexer connected to rows or columns of memory components.

In some embodiments of the present disclosure, a multi-processor computer system comprises a compact in-memory computer comprising memory components, each memory component comprising a compute engine and a storage element for storing data, the compute engine operable to read and process data stored only in the storage element of the memory component; and a processor external to the compact in-memory computer connected to and operable to write data to each storage element in the compact in-memory computer. The compute engine can comprise a bit multiplier (e.g., a single-bit multiplier or an iterative bit multiplier).

In some embodiments, the memory components are disposed in an array in which rows of memory components are connected to bit lines and columns of memory components are connected to word lines, or vice versa. In some embodiments, each compute engine comprises a capacitive product storage circuit and the capacitive product storage circuits of a row or column of memory components are connected together. Each compute engine in a row or column of memory components can comprise an iterative multi-bit multiplier.

According to some embodiments of the present disclosure, a multi-processor computer system comprises a compact in-memory computer comprising memory components, each memory component comprising a compute engine and a storage element for storing data, the compute engine operable to read data stored only in the storage element of the memory component through the bit line and process the data, and a processor external to the compact in-memory computer connected to and operable to write data to each storage element in the compact in-memory computer. The storage elements are mapped into a memory space of the processor and are accessible at memory addresses of the processor through the bit line. Thus, the storage element is connected to a bit line for writing a bit into the storage element with the processor and the compute engine is connected to the storage element with the same bit line, thereby providing a spatially dense configuration for the memory components of the compact in-memory computer. In some embodiments, the bit line is an internal bit line connected to an external bit line through a memory-select switch.

In embodiments of the present disclosure, the compact in-memory computer comprises a multiplexer disposed between and connected to the storage element and the compute engine and is operable to select bit cells in the storage element so that the compute engine is operable to process the data stored in the selected bit cells.

In some embodiments, the compute engine comprises a capacitor or current source.

In some embodiments, the compute engine comprises an analog-to-digital converter.

In some embodiments, the compute engine is operable to accumulate data stored in controllably selected bit cells.

In some embodiments, the compute engine is operable to convert data stored in the bit cells from an analog value to a digital value or to process data stored in the bit cells and convert the processed data from an analog value to a digital value.

In some embodiments, the compute engine operates using analog circuits.

In some embodiments of the present disclosure, a multi-processor computer system comprises a processor or controller external to the multi-processor computer system, the storage elements of the memory components are memory-mapped into a memory space of the processor or controller, and the processor or controller is operable to read and write data into any subset of the storage elements.

In some embodiments, at least some of the compute engines comprise bit multipliers that store bit products in capacitors, two or more of the capacitors are electrically connected in parallel and to an analog-to-digital converter, the analog-to-digital converter having a precision less than the maximum possible value of the accumulated bit products stored in the parallel-connected capacitors. In some embodiments, at least some of the compute engines comprise iterative bit multipliers that store accumulated bit products in a capacitor, the capacitor is electrically connected to an analog-to-digital converter, and the analog-to-digital converter has a precision less than the maximum possible value of the accumulated bit products stored in the parallel-connected capacitors. The analog-to-digital converter can be disposed in the compute engine or in the controller or external processor.

Some embodiments comprise a digital adder for adding partial accumulated sums each digitized by an analog-to-digital converter. The digital adder can be disposed in the compute engine, in the controller, or in the external processor.

Embodiments of the present disclosure provide fast, efficient, low-power, and compact digital storage and computing circuitry suitable for matrix multiplication, for example as is commonly found in pattern matching, machine learning, and artificial intelligence applications.

The multiplications can be done in parallel at the same time.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a schematic block diagram and inset of a compact in-memory computer architecture with an array of memory components each comprising a single compute engine (CE) in association with a bit memory according to illustrative embodiments of the present disclosure;

FIG. 2 is a schematic block diagram of a static random access memory (SRAM) according to the prior art;

FIG. 3A is a schematic block diagram of a compact in-memory computer architecture with an array of memory components each comprising a MEMSEL switch and a single compute engine (CE) in association with a byte of memory according to illustrative embodiments of the present disclosure;

FIG. 3B is a detail schematic block diagram of a controller and a memory component comprising bit cells and a compute engine according to illustrative embodiments of the present disclosure;

FIG. 3C is a detail schematic block diagram of a controller and a memory component storing multiple multi-bit values according to illustrative embodiments of the present disclosure;

FIG. 3D is a detail schematic block diagram of a controller and a memory component storing multiple multi-bit values with multiplexers according to illustrative embodiments of the present disclosure;

FIG. 3E is a detail schematic block diagram of a controller and a memory component storing a multi-bit value and accessing an external multi-bit value according to illustrative embodiments of the present disclosure;

FIGS. 4 and 5 are flow diagrams of methods according to illustrative embodiments of the present disclosure;

FIG. 6A is a schematic diagram of a simple bit cell and compute element according to illustrative embodiments of the present disclosure;

FIG. 6B is a schematic diagram of a more-complex bit cell and compute element according to illustrative embodiments of the present disclosure;

FIG. 7 is a block schematic diagram of an iterative bit multiplier according to embodiments of the present disclosure;

FIG. 8A illustrates columns of bits in a binary multiplication useful in understanding embodiments of the present disclosure;

FIG. 8B illustrates rows of bits in a binary multiplication useful in understanding embodiments of the present disclosure;

FIG. 9 is a schematic diagram illustrating multiple memory components with connected product capacitors according to illustrative embodiments of the present disclosure;

FIG. 10 is a simplified schematic diagram illustrating a two-dimensional array of memory components with columns of connected product capacitors and a controller according to illustrative embodiments of the present disclosure;

FIG. 11 is a simplified schematic diagram illustrating a one-dimensional array of memory components comprising iterative bit-product multipliers and a controller according to illustrative embodiments of the present disclosure;

FIG. 12 is a schematic block diagram of an in-memory compute architecture storing multi-bit values and a controller according to illustrative embodiments of the present disclosure;

FIGS. 13 and 14 are flow diagrams of methods according to illustrative embodiments of the present disclosure;

FIG. 15 is a block diagram of a multi-processor computer system according to illustrative embodiments of the present disclosure.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not necessarily drawn to scale.

### DETAILED DESCRIPTION OF CERTAIN EMBODIMENTS

Certain embodiments of the present disclosure, among other things, are directed towards compact in-memory computer architectures in which computing elements (CEs) are physically and spatially disposed between bit storage elements in a memory disposed over an area such as a substrate, for example a wafer or integrated circuit substrate, that can provide fast, efficient, low-power, and compact digital storage and computing circuitry suitable for matrix multiplication, for example as is commonly found in pattern matching, machine learning, and artificial intelligence applications. A compact in-memory computer architecture can be a computer comprising distributed memories and compute elements, for example useful in systolic computation systems, or a multi-processor computer system. The distributed memories can be memory-mapped into an external processor's memory space, allowing the external processor to read and write directly into the distributed memory.

The term ‘q’ is used herein in the text and figures to designate a bit and the suffix ‘B’ or ‘bar’, or a line (bar) placed over a value indicates an inverted value, for example qB (qBar) designates the inverted value of q (e.g., NOT(q) in Boolean terms).

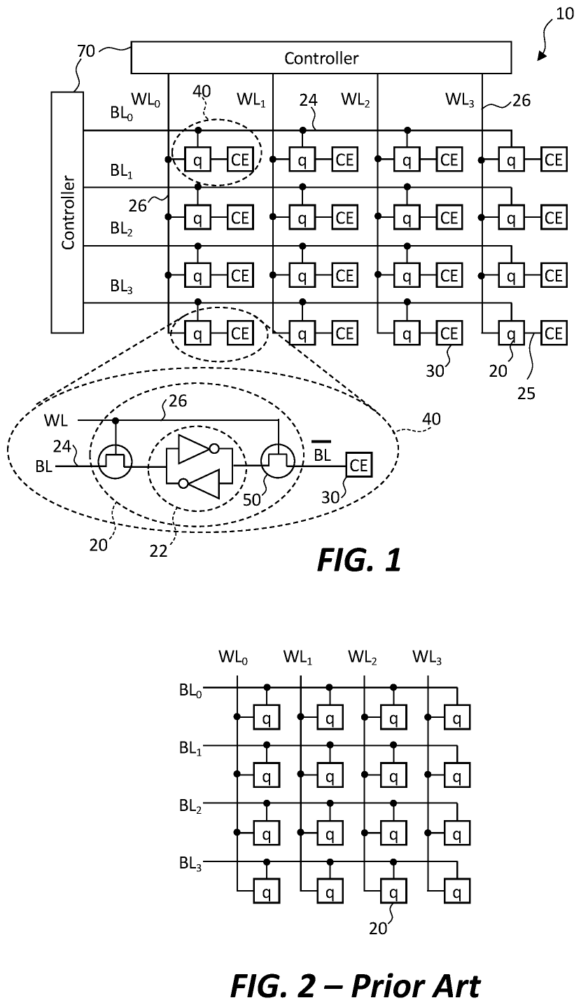

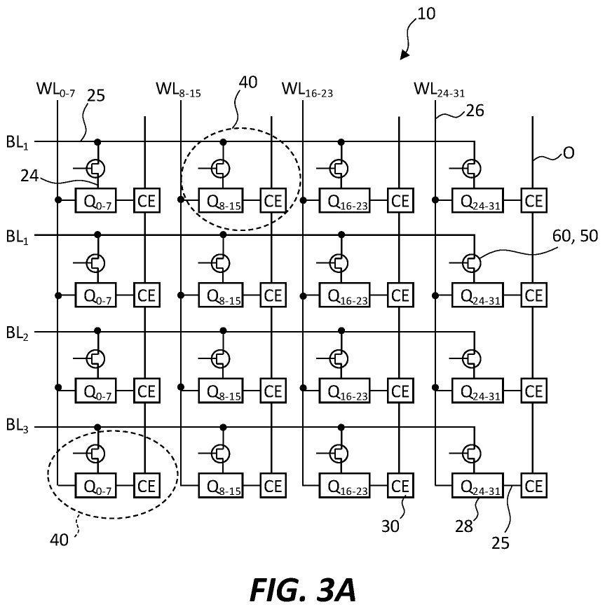

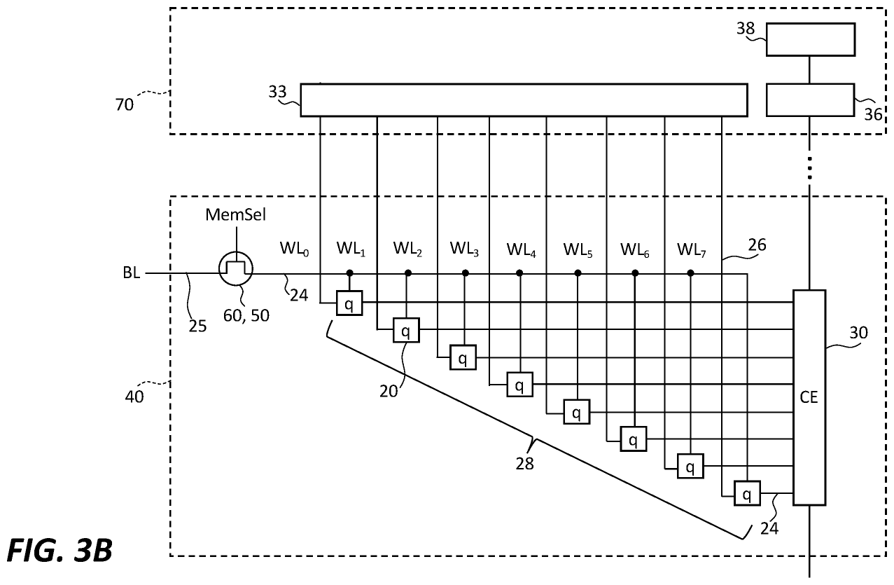

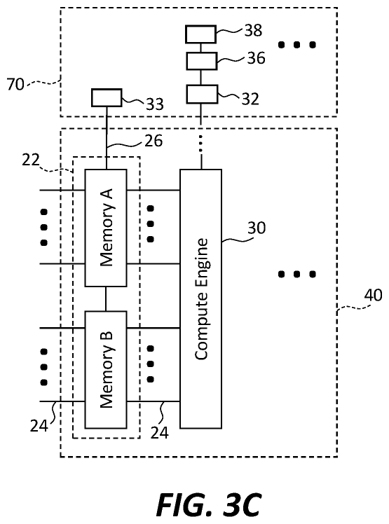

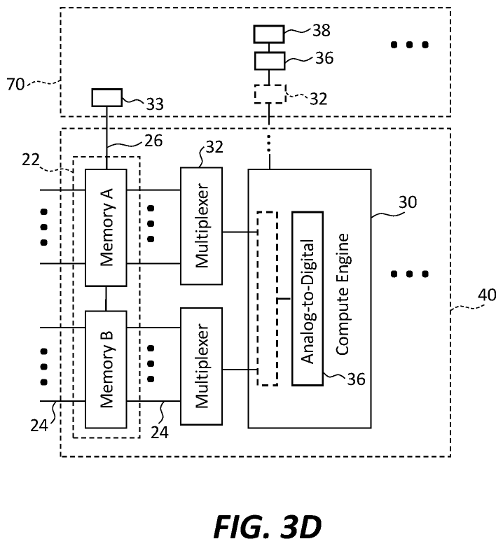

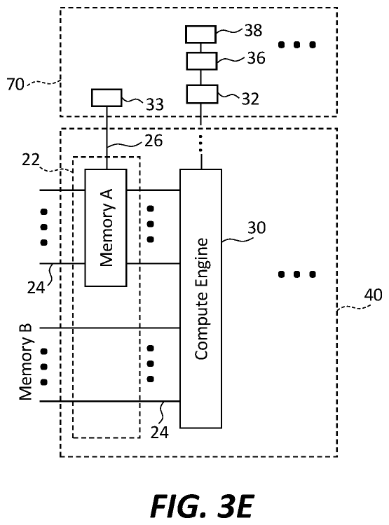

As illustrated in FIGS. 1, 3A, and 3B, a compact in-memory computer architecture 10 comprises memory components 40 arranged in rows and columns, a bit line 24 connected to each row of memory components 40, and a word line 26 connected to each column of memory components 40. Each memory component 40 comprises one or more bit cells 20 and a compute engine 30 (CE) connected to the one or more bit cells 20. Each bit cell 20 is a digital binary bit storage device or circuit operable to store a bit q of information (e.g., a one or a zero) and compute engine 30 is operable to access and process the bit(s), e.g., read the bit value(s) q stored in bit cell(s) 20 and perform a computational operation on the bit(s) q. Compute engines 30 can be hardwired compute engines 30 or can execute a program or state machine. In some embodiments, compute engines 30 are digital. In some embodiments, compute engines 30 are or comprise analog circuits, or a combination of analog and digital circuits.

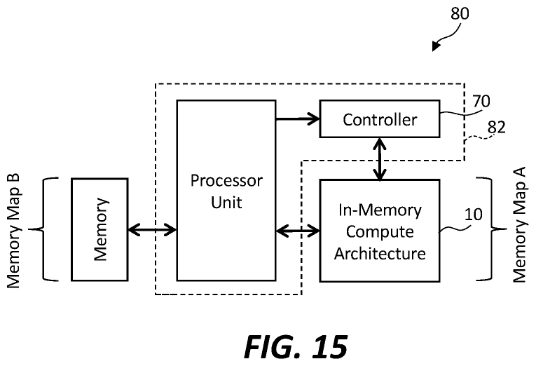

Bit lines 24 are electrical connections such as wires or traces operable to provide a bit q to each memory component 40 in a row of memory components 40. Word lines 26 are electrical connections such as wires or traces operable to provide a select or write signal to each memory component 40 in a column of memory components 40 to enable each memory component 40 in the column of memory components 40 to write a bit q into each memory component 40 in the column of memory components 40. Bit lines 24 and word lines 26 can be connected to and controlled by an external processor 82 or controller 70 (as discussed below with respect to FIG. 15). Memory components 40 can also comprise control signals or switches that can be externally controlled by controller 70. In some embodiments, word lines 26 can select bit cells 20 and controller 70 can read bits q stored in bit cells 20 on bit lines 24 and external bit lines 25 with an appropriate memory-select switch 60 setting.

Bit lines 24 and word lines 26 provide matrix access to the rows and columns of memory components 40. Thus, controller 70 can comprise a row controller operating in combination with a column controller to provide control signals to the array of memory components 40, for example row or column select, data, or write signals. In some embodiments, controller 70 provides address and data signals that are operable to write data into the array of memory components 40 in compact in-memory computer architecture 10, for example using an interface similar to a conventional memory.

FIG. 1 illustrates each bit line 24 with a subscript value representing each individual bit line 24 (e.g., BL₀, BL₁, etc.). Similarly, FIG. 1 illustrates each word line 26 with a subscript value representing each individual word line 26 (e.g., WL₀, WL₁, etc.). Bit cells 20 can comprise a digital binary bit storage element 22, for example a flip flop, latch, or SRAM cell. Access to bit storage element 22 can be controlled by transistors 50 (e.g., an electronic switch) with a gate controlled by a word line 26 and with read or written data on bit lines 24, for example by controller 70. Bit line 24 (or a portion of bit line 24) can also connect to compute engine 30, providing a compact layout for memory components 40. According to embodiments of the present disclosure, compact in-memory computer architecture 10 can leverage very compact layouts for SRAMs to reduce the area used by compact in-memory computer architecture 10.

FIG. 2 illustrates a prior-art SRAM comprising bit storage elements 22 arranged in rows and columns and connected to bit lines 24 and word lines 26.

FIG. 3A illustrates embodiments of the present disclosure in which each memory component 40 is connected to an external bit line 25 through a memory select (MEMSEL) switch 60 (e.g., a transistor 50). MEMSEL switch 60 can isolate or connect bit line 24 (e.g., an internal bit line 24) of each memory component 40 from or to external control or data circuits (e.g., external bit line 25 and controller 70 as shown in FIG. 1). (For clarity, controller 70, as shown in FIG. 1 is omitted from FIG. 3A but can be incorporated into FIG. 3A.) MEMSEL switch 60 of each row, column, or the entire array of memory components 40 can be electrically connected in common so that a single control signal can isolate or connect bit lines 24 in a corresponding row, column, or array of memory components 40, e.g., a common control signal connected to a gate of MEMSEL switch 60 transistor 50 of rows, columns, or the array of bit cells 20. Thus, MEMSEL switch 60 can enable external access to bit cells 20, e.g., as a memory-mapped memory array, with commonly connected external bit lines 25 in a first mode and isolate bit cells 20 from external access in a second mode so that bit cells 20 are individually, independently, and separately accessible by corresponding compute engines 30 in each memory component 40.

As is also shown in FIG. 3A and in the details of FIGS. 3B and 3C, each memory component 40 can comprise multiple bit storage elements 22 or bit cells 20 connected to a common compute engine 30. In particular, multiple bit cells 20 can comprise bit storage element 22 providing a word store 28 storing multiple bits of one or more multi-bit digital values that can be accessed and processed by compute engine 30, e.g., as shown in FIG. 3B. Word store 28 can store, for example, any of 4 bits (e.g., a nibble), 8 bits (e.g., a byte), 16 bits (e.g., a word), 24 bits, 32 bits (e.g., a long word), 48 bits, 64 bits, 96 bits, 128 bits, 256 bits, 512 bits, or 1024 bits, or more. In some embodiments, memory components 40 can each comprise multiple bit storage elements 22 or bit cells 20 that store multiple multi-bit digital values accessed and processed by a single compute engine 30 in memory component 40, as shown in FIG. 3C. Each bit cell 20 of the multiple bit cells 20 (or bit storage elements 22) can be connected to a common bit line 24 and to a different word line 26 to enable writing bits into each bit cell 20. Word line 26 can enable access to a specific bit by compute engine 30. In some embodiments, the outputs of each bit cell 20 can be connected together so that only one, or fewer than the number of bit cells 20, can be connected to compute engine 30 with a single connection. Thus, a single bit q in a bit cell 20 connected to a bit line 24 can be selected by a corresponding word line 26 and operated upon by compute engine 30 at a time or multiple bits, but fewer than all bits q, are selected and operated upon by compute engine 30 at a time, or all bits q in a memory component 40 are selected and operated upon by compute engine 30 at a time. Thus, in some embodiments and as shown in FIG. 3B, each bit cell 20 is connected directly to compute engine 30 and can be accessed in parallel at a single time.

In some embodiments of the present disclosure and as shown in FIG. 3C, compact in-memory computer architecture 10 comprises a controller 70 for controlling memory components 40. In some embodiments and as shown in FIG. 3C, each bit line 24 or word line 26 is connected to a demultiplexer 33 in controller 70 that provides bits or address selections to each row or column of bit cells 20 at a time to compute engine 30 so that rows and columns of bit cells 20 are written sequentially or, in some embodiments writes data to each bit cell 20 at a time. Similarly, controller 70 can comprise a multiplexer 32 that receives data from compute engines 30 in rows or columns of memory components 40 and can select data from each row or column at a time to selectively input data.

In some embodiments, and as shown in FIG. 3D, compact in-memory computer architecture 10 can comprise a multiplexer 32 (or multiple multiplexers 32) disposed between storage element 22 and compute engine 30 controlled by compute engine 30 or controller 70. Multiplexer(s) 32 can enable compute engine 32 to select one or more bit cells 20 in storage element 22 and process the bits stored in each selected bit cell 20. Multiplexer(s) 32 can be separate and independent of compute engine 30 or compute engine 30 can comprise multiplexers 32. Selected data or processed selected data can be converted from an analog form to a digital value with analog-to-digital converter 36. Some embodiments comprise multiple multiplexers 32 and multiple analog-to-digital converters 36 so that each multiplexer 32 selects data for a separate analog-to-digital converters 36.

In some embodiments of the present disclosure and as shown in FIG. 3E, a single bit or multi-bit value (e.g., memory A) is stored in memory component 40 and a second bit or multi-bit value (e.g., memory B) is externally accessed by compute engine 30 and processed in combination with memory A under the control of controller 70. As in the embodiments illustrated in FIG. 3D, one or more multiplexers 32 can enable compute engine 30 to select one or more bit cells 20 in storage element 22 (not shown in FIG. 3E).

Memory components 40 can be disposed on a substrate (e.g., a wafer such as a silicon wafer or printed circuit board) and each memory component 40 can be spatially disposed on or over a different portion of the substrate and adjacent to another memory component 40. Compute engine 30 of each memory component 40 can be disposed spatially adjacent to bit cell 20 of each memory component 40, as illustrated in FIGS. 1 and 3A. In some embodiments, at least one of compute engines 30 in memory components 40 can be spatially disposed between bit cell 20 of a memory component 40 and bit cell 20 of an adjacent memory component 40, for example as illustrated in FIGS. 1 and 3A. A bit line 24 connected to a bit cell 20 can also connect bit cell 20 to compute engine 30 in a memory component 40, providing an efficient use of space on or in a wafer or integrated circuit and reducing the area required by memory components 40.

Adjacent bit cells 20 are bit cells 20 between which no other bit cell 20 is located and adjacent memory components 40 are memory components 40 between which no other memory components 40 is located. Similarly, adjacent compute engines 30 are compute engines 30 between which no other compute engine 30 is located. In some embodiments, each compute engine 30 is connected to an adjacent compute engine 30, e.g., with electrical connections). Such arrangements of bit cells 20 and compute engines 30 in memory components 40 provides for a compact and efficient structure that reduces the area of used (e.g., silicon area in a wafer or integrated circuit), locates the circuits close to each other to reduce signal propagation time and improve signal-to-noise ratio, and leverages, is compatible with, or extends circuit layouts commonly found in highly optimized integrated circuit layouts in integrated circuit foundries or fabrication facilities. Thus, embodiments of the present disclosure use semiconductor resources efficiently, reducing costs and providing excellent performance.

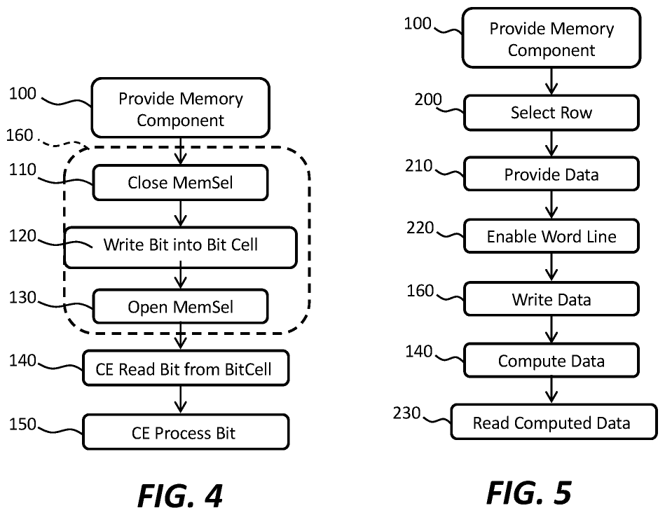

FIG. 4 illustrates the operation of embodiments of the present disclosure corresponding to FIG. 3A. In step 100, one or more memory components 40 are provided, for example an array of memory components 40 connected with bit lines 24 and word lines 26 as illustrated in FIG. 3A. In step 110, MEMSEL switch 60 is closed (e.g., by controller 70) to connect internal bit lines 24 to external bit lines 25 and to controller 70. Controller 70 selects a column of memory components 40 and provides corresponding signals (e.g., bit values q) on external bit lines 25) that travel through the closed MEMSEL switches 60 to internal bit lines 24 and are stored in bit storage elements 22 of each bit cell 20 in step 120. In this mode, bit cells 20 in memory components 40 can act as a conventional SRAM, for example as shown in FIG. 2.

MEMSEL switches 60 are then opened (e.g., by controller 70) to isolate memory components 40 from external bit lines 25 in step 130 to complete a write step 160. Compute engine 30 can then independently access the connected bit cell 20 in each memory component 40 to read the bit value q in step 140 and then process bit value q in step 150.

Thus, methods of the present disclosure comprise operating a compact in-memory computer architecture 10 as illustrated in FIG. 5 by providing memory components 40 in step 100 and using controller 70 to select a row of memory components 40 in step 200, providing a bit q on each bit line 24 (e.g., provide data) in step 210, enabling word line 26 of each column of memory components 40 in step 220, and storing the bit q into bit cell 20 of each memory component 40 in the selected row of memory components 40 in step 160. The stored bit q is processed in step 140 using compute engine 30 of each memory component 40 in the column of memory components 40. Each memory component 40 can be connected to a corresponding bit line 24 through a memory select (MEMSEL) switch 60 and methods of the present disclosure can comprise using controller 70 to turn MEMSEL switch 60 on before using controller 70 to provide the bit q on each bit line 24 and to turn MEMSEL switch 60 off after using controller 70 to provide the bit q on each bit line 24 (step 160) before using compute engine 30 of each memory component 40 in the column of memory components 40 to process the stored bit q in step 140. The processed data can be read in step 230, for example by controller 70.

According to some embodiments of the present disclosure, bit cells 20 (e.g., SRAM bit storage) can be implemented with 6 transistors so that word stores 28 for a byte (an eight-bit multi-bit digital value) require forty-eight transistors and word stores 28 for a word (a sixteen-bit multi-bit digital value) require ninety-six transistors. In some embodiments, compute engines 30 can comprise twelve transistors and two capacitors so that the integration of compute engines 30 into an optimized, dense, and efficient SRAM array design from a semiconductor foundry or fabrication facility results in a comparably optimized, dense, and efficient memory component design.

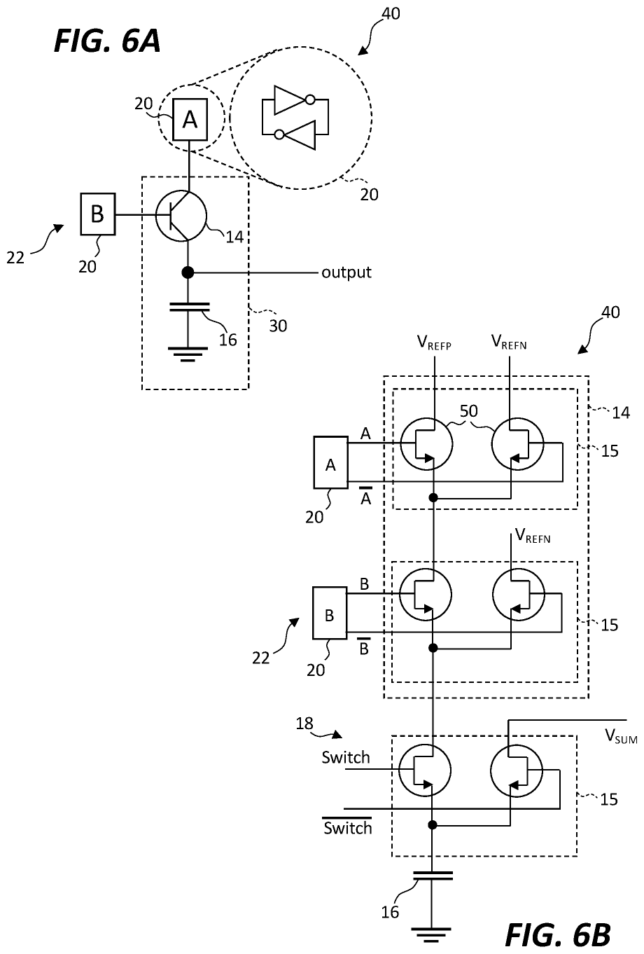

As noted, compute engine 30 can comprise both analog and digital circuit elements, for example capacitors and transistors. As shown in FIG. 6A, a memory component 40 comprises multiple bit cells 20 (forming storage element 22) and a compute engine 30 operable to read data from bit cells 20 A and B. Compute engine 30 can comprise a one-bit multiplier 14 (e.g., a switch 50 or transistor 50) that receives input from bit cells 20. One input (e.g., bit cell 20 B) is connected to the gate, another input (e.g., bit cell 20 A) is connected to the source. When data in both bit cells 20 A and B are high (e.g., a one), a one is transferred to transistor 50 drain and is accumulated in a product storage circuit 16 (e.g., an analog storage circuit 16 such as a capacitor 16) as the product of bit data stored in bit cells 20 A and B.

FIG. 6B illustrates a more complex, electrically efficient, and spatially efficient bit-multiply circuit 14. In some such embodiments, a serial switch circuit 15 comprises two transistors 50 driven by complementary outputs from a bit-cell 20. If bit cell 20 is high (e.g., stores a one or a positive charge) A V_{REFP} signal (positive voltage reference) is transferred through serial switch circuit 15. Each of two serial switch circuits 15 connected in series is connected to bit cell 20 A and bit cell 20 B, respectively. If both are positive, a positive value (e.g., a one or a positive charge) is deposited in product storage circuit 16 (e.g., an analog storage circuit 16 such as a capacitor 16) as the product of bit data stored in bit cells 20 A and B when switch circuit 18 (switch 18) is high. If either of bit cells 20 A or B is low, a low or zero charge value is stored in product storage circuit 16. If switch circuit 18 is low (e.g., a zero) the charge (voltage) in product storage circuit 16 is output. Thus, switch circuit 18 is operable to store a bit product in a multiplication mode and operable to output the bit product in an accumulate mode, but not both modes at the same time.

Memory component 40 shown in FIG. 6B comprises three serially connected serial switch circuits 15. Each switch circuit 15 comprises a pair of simple MOS (metal-oxide semiconductor) transistors having separate differential inputs and a common output. One of the pair of simple MOS transistors is controlled by a positive control signal and the other by an inverted (negative) version of the same control signal, for example the positive and negative outputs of any single-bit cell 20 (e.g., a D-flipflop or pairs of inverters). Such a series of serial switch circuits 15 can require fewer, simpler transistors that operate at a much lower voltage (e.g., one percent or less than one percent, such as 0.624 percent, or 10 mV instead of 1.65 volts) and therefore require much less power. The combined (added) voltage on analog storage circuits 16 can be:

$$\begin{matrix}{V}_{SUM} = ( ( n * {V}_{REFP} ) + ( N - n ) * {V}_{REFN} ) ) / N . \\ Where {V}_{REFN} = 0 volts : \\ {V}_{SUM} = ( n * {V}_{REFP} ) / N\end{matrix}$$

where n is the number of capacitors and N the number of parallel-connected capacitors 16 connected in a row.

In some embodiments, bit multiplier 14 very precisely controls the current depositing charge on bit capacitor 16 over time to maintain the accuracy and precision of the multiply-accumulate operation. Thus, bit multiplier 14 can be designed to very precisely control the amount of charge deposited on bit capacitor 16, for example responsive to a carefully calibrated timing signal and voltage. A bit-multiplier 14 using a conventional AND gate can require, for example, six relatively large transistors operating at a relatively high voltage to implement a bit-multiply circuit that can adequately control the charge Q deposited on analog storage circuit 16 (e.g., from 1.65-5 V). In contrast and according to embodiments of the present disclosure, bit-multipliers 14 of the present disclosure can comprise serially connected serial switch circuits 15 that can operate at relatively low voltages (e.g., no greater than 1 V and as low as 10 mV) and low power and can adequately control the charge Q deposited on analog storage circuit 16 with, for example, only four relatively small transistors. In embodiments, memory component 40 operates in an analog relatively low-power regime having an analog voltage that is less than a digital relatively high-power regime having a digital voltage. In some embodiments, the analog voltage is no greater than one-half, one quarter, one fifth, one tenth, one twentieth, one fiftieth, or one hundredth (e.g., 50%, 25%, 20%, 10%, 5%, 2%, or 1%) of the digital voltage.

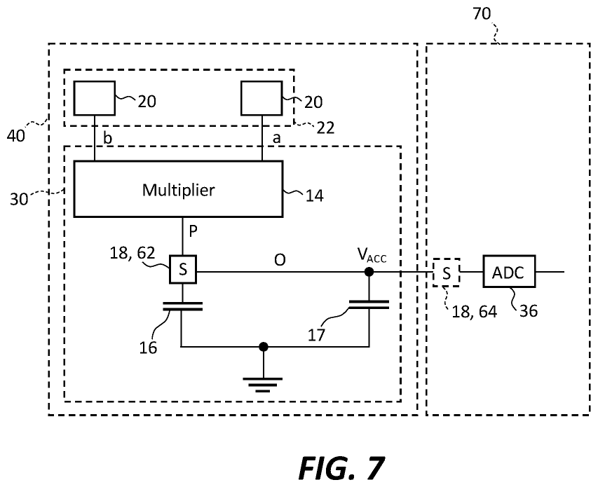

In some embodiments, bit products are iteratively combined and successively scaled by factors of two to provide a multi-bit multiplication product. As shown in FIG. 7, bit products can be stored in product storage circuit 16 when switch 18 connects bit multiplier 14 to capacitor 16. When switch 18 connects capacitor 16 to accumulator storage circuit 17 (capacitor 17), the charges are averaged. Each successive bit product (either a zero or a one), will average the accumulator charge to either one half of the charge (if the bit product is a zero) or one half the difference between the accumulator charge and one (if the bit product is a one). Thus, the resulting accumulator charge is a multi-bit product that can be converted to a digital value (scaled by the number of averaging steps).

FIG. 7 illustrates a simple hybrid iterative single-bit multiply-accumulate circuit comprising the single-bit multiply-accumulate circuit of FIG. 6B (shown with logical rather than electrical operation) with a product storage circuit 16 (capacitor 16) electrically connected in parallel with an accumulator storage circuit 17 (e.g., a capacitor 17 having the same capacitance as product storage circuit 16) by switch 18 which serves as an accumulation switch 62. Accumulation switch 62 can be the same as, substantially similar to, or identical with differential switch 18 of serial switch circuits 15. Optionally, the output of accumulator storage circuit 17 can be connected through an optional switch 18 (output switch 64) to an analog-to-digital converter (ADC) 36.

In more detail, FIG. 7 shows the multiplication of two single-bit values stored in two corresponding single-bit cells 20 of a storage element 22. When switch 18 is set in multiplication mode (high), product P is stored in product storage circuit 16 (capacitor 16). When switch 18 is set to accumulate mode (low), any charge stored in product storage circuit 16 is shared (combined) with any charge stored in accumulator storage circuit 17 (capacitor 17). The average of the charges in capacitors 16 and 17 is then stored in both capacitors 16 and 17. Multiple bit products can be accumulated in the two capacitors 16, 17 by repeatedly providing bits in bit cells 20 A and B, setting switch 18 in multiplication mode, depositing a charge representing the bit product of bit cells 20 A and B in product storage circuit 16, and setting switch 18 in accumulation mode to combine the charge in capacitor 16 and capacitor 17 (accumulator storage circuit 17). When all of the bits are multiplied, the result can be output by setting accumulation switch 62 high. The analog charge can then be converted to a digital value and scaled to represent the product of the bits iteratively provided in bits cells 20 A and B.

In embodiments of the present disclosure, the iterative bit multiplication proceeds from the least-significant bit to the most-significant bit. Each time product values are averaged; they are also divided by two so that the next bit will have twice the relative value as the accumulated value. For example, a digital value of 11₁₀ (1011₂) would proceed by clearing the product and accumulator storage circuits 16, 17 (capacitors 16, 17). Given a single bit A equal to 1 (if the single bit A is equal to zero, all of the products and accumulated charges will be zero), the least significant bit (bit zero) of multi-bit value B is one, so the product will be one, and a one value will be transferred into capacitor 16 in a first iteration. (The actual charge is a design choice, the values described in this example are relative values and quantities of charge.) The accumulated value will be one half (shared between capacitors 16 and 17). The next bit (bit one) will also result in a product of one, so capacitor 16 is set to a one value and, when combined with the one half value in accumulation capacitor 17, results in a value of three quarters. The next product using the zero bit two of multi-value B will set capacitor 16 to zero and, when shared with the three quarters accumulated value results in a value of three eighths (three quarters divided by two). The final bit (bit 3) of multi-value A is a one, resulting in a capacitor 16 value of one that, when shared with the three eighths value in capacitor 17, results in a final product of eleven sixteenths. The product (scaled by sixteen to adjust for the averaging at each of four stages, is eleven, the product of eleven and one. The process can then be repeated with another bit of multi-bit value A, computing all of the bit products for two multi-bit values A and B.

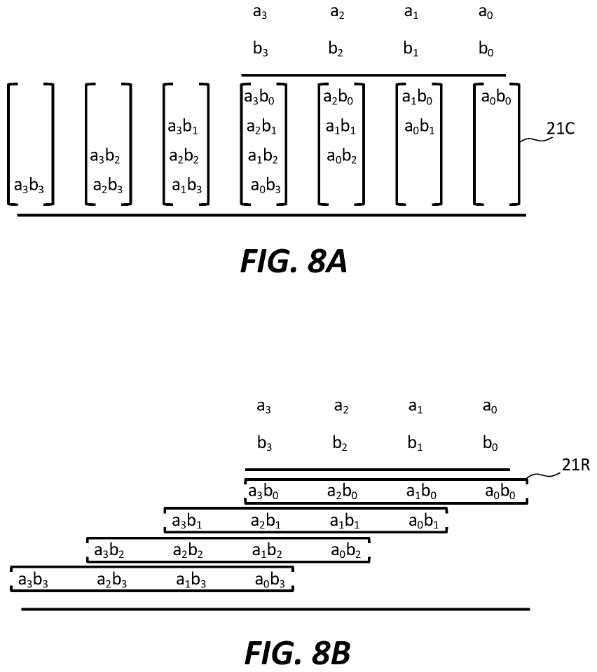

As illustrated in the 4-bit example of FIGS. 8A and 8B, each row of products shown is a multiplication of one bit of value B times the bits of value A. The rows are spatially shifted with respect to each other in FIGS. 8A and 8B to represent the relative magnitude (place) of the products in each row as is conventional for multiplication manually written on paper. The bit products (multiplied values) in each bit column 21C of products (having the same magnitude or place) can be summed. Each column sum has a relative magnitude of two (or one half) with respect to a neighboring bit column 21C, as shown in FIG. 8A. Because each bit column 21C of products has a different place value (relative magnitude) the values in each column 21 of products must be scaled to multiply them by their place value, e.g., by one to 6 places to multiply them by 2, 4, 8, 16, 32, or 64, before they are added. Scaling and adding the column sums provide a product for the two multi-bit digital binary values A and B. Similarly, the bit products (multiplied values) of each bit row 21 R of products can be appropriately scaled and summed, as shown in FIG. 8B. Each bit product in a row has a relative magnitude of two (or one half) with respect to a neighboring bit product in the row and each row has a relative magnitude of two (or one half) with respect to a neighboring row. Scaling and adding the row sums provide a product for the two multi-bit digital binary values A and B.

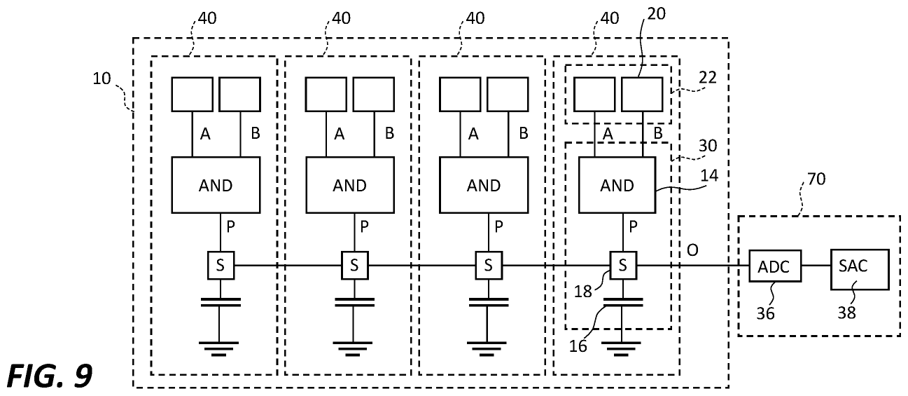

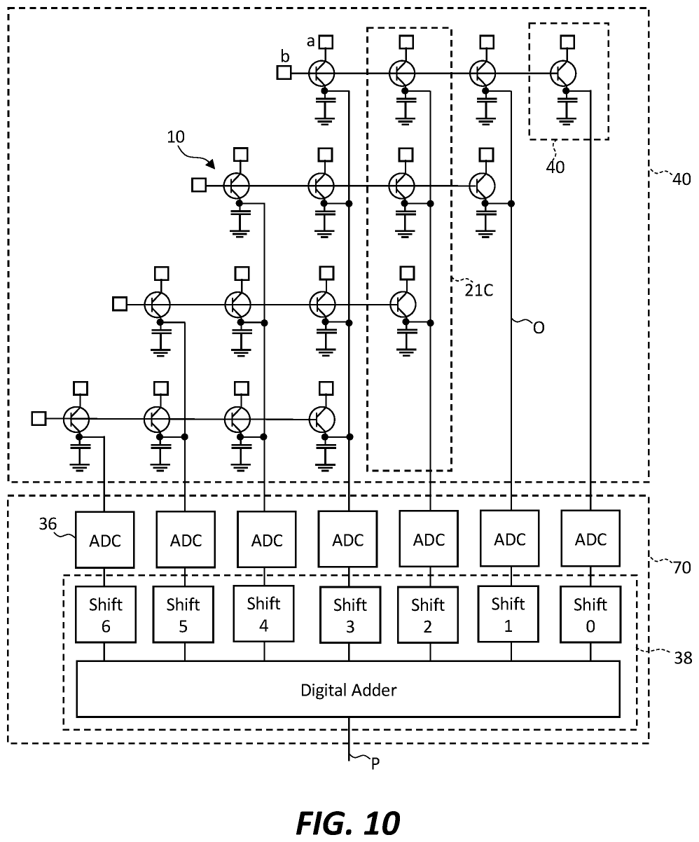

FIG. 9 is a schematic that illustrates embodiments corresponding to FIG. 8A. In FIG. 9, each capacitor 16 in a column of memory components 40 is connected together when switch S is in accumulate mode. The values are averaged, and the average values can be converted to a digital value, scaled, and summed to provide a product of the two multi-bit values. FIG. 10 is a more detailed illustration showing an array of capacitors 16 of (simplified as in FIG. 6A) memory components 40 in a common bit column 21C connected together. The summed products of each bit column 21C (outputs O) are converted to a digital value by analog-to-digital converters 36 and then shifted (e.g., with a shift register or simply by connecting bits in a shifted arrangement to a digital adder providing a product P in a digital-shift-and-accumulate circuit 38.

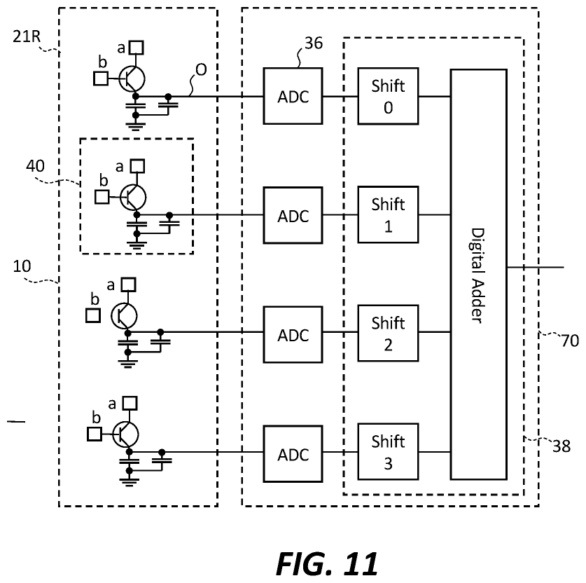

FIG. 11 illustrates an array of memory components 40 according to FIG. 7 that iteratively calculate and scale the product of a bit row 21 R. Each memory component 40 iteratively calculates the sum O of a bit row 21 R and sums O are converted to digital values with ADCs 36 and then shifted and summed in digital shift-and-accumulate circuit 38 to provide a product P.

The embodiments of FIGS. 9 and 10 are faster than the embodiments of FIG. 11, since no iterative calculations are needed but, instead, require a two-dimensional array of memory components 40 to compute the product of two multi-bit binary values. The embodiments of FIG. 11 require an iterative bit-product sum but require only a one-dimensional array of memory components 40. In both embodiments, large arrays of memory components 40 can calculate many products simultaneously, for example many millions or even billions. (For clarity of illustration, FIGS. 10 and 11 show memory components 40 using the configuration of FIG. 6A, but the configuration of FIG. 6B can likewise be used.) Compute engine 30 can comprise a variety of different computational structures, including analog circuits, digital circuits, or a combination of analog and digital circuits. Similarly, the processing operations performed by compute engine 30 are not limited and can include logical, programmatic, and mathematical operations. Compute engine 30 can comprise control circuits, state machines, or programmable machines, including registers, clock signals, and arithmetic structures such as adders and multipliers. In some embodiments, compute engine 30 can write processed data into storage element 22 and the process data in storage element 22 can be read by processor 70, for example by selecting memory components 40 with word lines 26 and reading the data on bit lines 24 (e.g., through memory-select switch 60 connecting external bit lines 25).

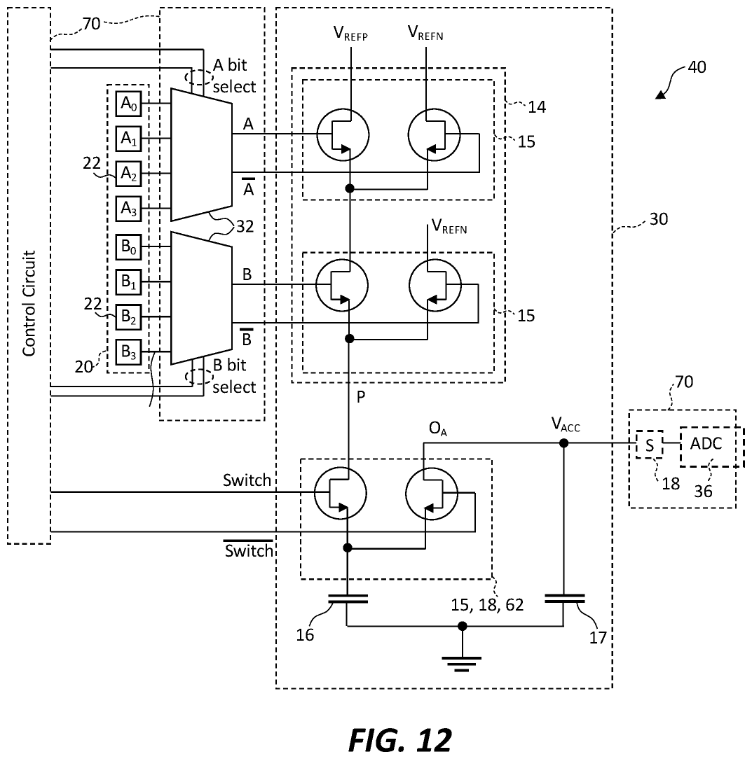

In some embodiments of the present disclosure and as illustrated in FIG. 12, compute engine 30 enables the multiplication of two multi-bit values stored in storage element 22 and compact in-memory computer architecture 10 comprising multiple memory components 40 performs matrix multiplication on values stored in storage elements 22. In some embodiments, compact in-memory computer architecture 10 provides an array of dot product functions that can be a matrix vector product (e.g., where a matrix dimension is one). Each row (or column) of memory components 40 in a compact in-memory computer 10 can perform a dot product.

Thus, in some embodiments, memory component 40 comprises compute engine 30 comprising a multiplier and a storage element 22 with two elements A and B, each comprising an arbitrary number of bits. Compute engine 30 is connected to storage element 22 with data lines (bit lines 24) and writes and reads and to and from storage element 22 using control signals. In operation, data is written into storage elements 22 using bit and word lines 24, 26 with memory-select switch 60 enabled (FIG. 3A). When memory-select switch 60 is not enabled, compute engine 30 can read data from storage element 22, operate on (process) the read data. Storage elements 22 of compact in-memory computer architecture 10 can be memory mapped to controller 70. Controller 70 can write data into storage elements 22 in such a way that compute engines 30 each compute the appropriate portion of a multi-bit multiplication, e.g., using demultiplexers 33.

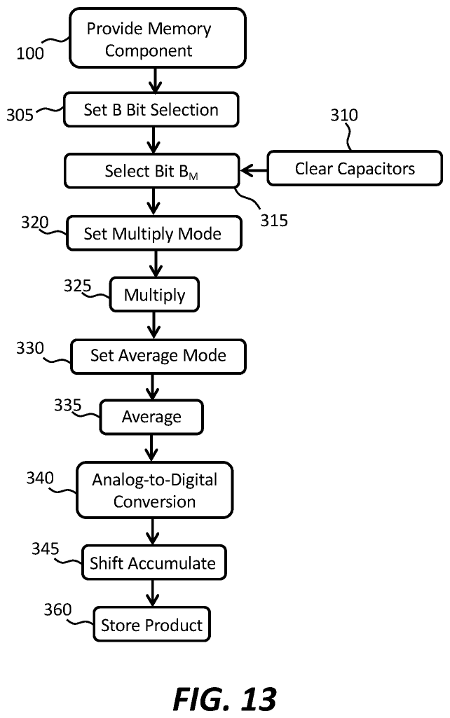

As shown in the circuit diagrams of FIGS. 9 and 10 and flow diagram of FIG. 13, a single bit A can be multiplied by a multi-bit value B by first providing a memory component 40 in step 100 and then clearing product storage circuit 16 and accumulator storage circuit 17 in step 310 (e.g., set their values to zero, for example by connecting them to ground with a clear circuit to remove any charge in capacitors 16, 17). A bit-count M is set for each memory component in step 305. Steps 305 and 310 can be done in any order. Controller 70 selects a single-bit value A from storage element 22 and a multi-bit value B in storage element 22 in step 315 to select bit M of multi-bit value B by multiplexer 32 and switch 18 is set to multiplication mode under the control of controller 70 in step 320. Bit multiplier 14 multiplies single-bit value A by bit B_{M} in step 325. Switch 18 is set to average mode under the control of controller 70 in step 330 so that the charge in capacitors 16 and 17 are shared (averaged) in step 335. The averaged value can be converted to a digital value in step 340 and shifted and accumulated in step 345. An accumulated value corresponding to the product can be stored in step 360.

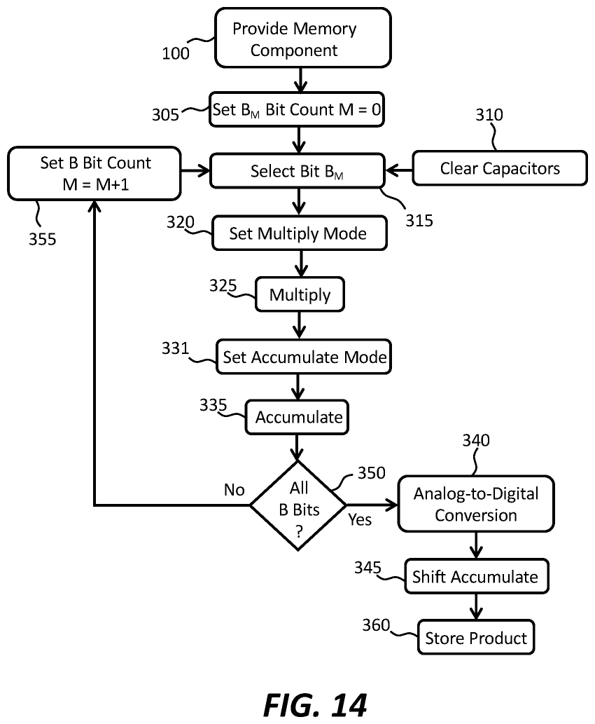

FIG. 14 illustrates an iterative method useful for the circuit of FIG. 12 and is similar to FIG. 13 except that, rather than averaging, the bit values are iteratively multiplied and accumulated in steps 325 and 335 before conversion to a digital value and accumulated for each of the multiple bits in one of the multi-bit values. In the flow diagram of FIG. 14, a single bit A can be multiplied by a multi-bit value B by first providing a memory component 40 in step 100 and then clearing product storage circuit 16 and accumulator storage circuit 17 in step 310 (e.g., set their values to zero, for example by connecting them to ground with a clear circuit to remove any charge in capacitors 16, 17). A bit-count M is set to zero in step 306. Steps 306 and 310 can be done in any order. Controller 70 selects a single-bit value A from storage element 22 and a multi-bit value B in storage element 22 in step 315 to select bit M of multi-bit value B by multiplexer 32 and switch 18 is set to multiplication mode under the control of controller 70 in step 320. Bit multiplier 14 multiplies single-bit value A by bit B_{M} in step 325. Switch 18 is set to accumulation mode under the control of controller 70 in step 331 so that the charge in capacitors 16 and 17 are shared (averaged and accumulated) in step 335. If all B bits are not multiplied (step 350), bit count M is incremented in step 355 and the next bit is selected (step 315) and the process repeats until all bits M are iteratively multiplied and accumulated. The accumulated value can be converted to a digital value in step 340 and shifted and accumulated in step 345. An accumulated value corresponding to product P is stored in step 360.

According to embodiments of the present disclosure, compact in-memory computer architecture 10 comprises many memory components 40 (e.g., many thousands, millions, hundreds of millions and even billions of memory components 40 comprising both storage elements 22 and compute engines 30). Thus, compact in-memory computer architecture 10 can perform many millions and even billions of bit multiplications at a very high rate with very little power. An external processor 82 (see FIG. 15), for example a central processing unit (CPU) or external FPGA with appropriate control circuits such as a processor unit or state machine, can write data to memory components 40 and then almost immediately receive processed data from memory components 40, providing a very simple and very fast architecture for processing large amounts of data in parallel. Because storage elements 22 of memory components 40 in compact in-memory computer architecture 10 can be mapped into the memory space of an external CPU or other processor 82, an interface to compact in-memory computer architecture 10 is very simple (the same as, similar to, or substantially like) an interface to a memory (e.g., a DRAM or SRAM). Because there are many compute engines 30 in compact in-memory computer architecture 10 and because the multiplying, summing, analog-to-digital conversion, and shifting operations can be analog, data processing can be extremely fast.

Embodiments of the present disclosure can be very compact, leveraging or using structures similar to those found in memory chips. To provide a dense arrangement of memory components 40, it can be useful to integrate small and efficient compute engines 30 in compact in-memory computer architecture 10. In some embodiments, memory components 40 are arranged in a two-dimensional array (matrix) with rows of memory components 40 (e.g., storage elements 22 of each memory component 40 in a row of the array) connected to a common bit line 24 and columns of memory components 40 (e.g., storage elements 22 of each memory component 40 in a column of the array) connected to a common word line 26.

In some embodiments, memory components 40 are arranged in a two-dimensional array (matrix) with rows of memory components 40 (e.g., storage elements 22 of each memory component 40 in a row of the array) connected to a common word line 26 and columns of memory components 40 (e.g., storage elements 22 of each memory component 40 in a column of the array) connected to a common bit line 24. Rows and columns are arbitrary designations of orthogonal groups of memory components 40 in an array and can be interchanged.

In some embodiments, memory components 40 are interconnected in a matrix. In some embodiments, memory components 40 are physically and spatially disposed in an array with rows and columns of memory components 40 arranged in a two-dimensional array (matrix) with rows of memory components 40 (e.g., storage elements 22 of each memory component 40 in a row of the array) connected to a common bit line 24 and columns of memory components 40 (e.g., storage elements 22 of each memory component 40 in a column of the array) connected to a common word line 26 over an area of a substrate on which memory components 40 are disposed. Compute engines 30 of each memory component 40 can be disposed between storage element 22 of memory component 40 and storage element 22 of an adjacent memory component 40, for example adjacent in a horizontal direction or adjacent in a vertical direction (or both). Adjacent memory components 40 are memory components 40 between which no other memory component 40 is spatially disposed.

According to embodiments of the present disclosure and as illustrated in FIG. 15, a multi-processor computer system 80 comprises a processor 82 comprising controller 70 or controller 70 can be processor 82. The processor can be a central processing unit operable to read and write data from and to a processor address space. In some embodiments, a memory is connected to the central processing unit mapped into the processor memory space (e.g., a processor address space B having a range of processor-memory addresses in the processor address space) of the central processor unit for storing programs and data, e.g., a stored program machine. In some embodiments, processor 82 comprises a custom integrated circuit (or circuits), a programmable gate array (e.g., PGA), a field programmable gate array (e.g., FPGA), or state machine comprising storage and functional elements. Controller 70 can control or otherwise provide data to and receive data from compact in-memory computer architecture 10 and can be implemented within a program of processor 82 or comprise a peripheral control circuit (e.g., a SEPARATE controller 70) implemented in any combination of customer circuits, programmable gate arrays, state machines or other electronic or optoelectronic circuits. Processor 82 can access storage elements 22 of memory components 40 of compact in-memory computer architecture 10 as a memory array mapped into the memory space of processor 82, for example in an address range corresponding to a processor address space A having a range of addresses different from the range of addresses of processor address space B.

In embodiments, compact in-memory computer architecture 10 is compact in-memory computer 10 or a compact in-memory computer 10 can be or comprise compact in-memory computer architecture 10 that is a distributed memory (e.g., storage elements 22 distributed over an area of a substrate such as a semiconductor wafer substrate) with compute engines 30 (e.g., as shown in any of FIGS. 1-3C, 6A-7, and 8-12) spatially disposed between storage elements 22 of different adjacent memory components 40 to provide a compact structure capable of massively parallel processing (e.g., multiplications such as bit multiplications or iterative bit multiplications that are accumulated to provide products of two multi-bit values in a matrix multiplication), for example useful in machine learning and artificial intelligence applications with reduced power and increased speed, for example provided by using analog operations, analog storage (e.g., capacitors rather than flip-flops or latches), analog summing, or analog scaling (e.g., as part of an iterative multi-bit multiplication). Multiple multiplications of different values in a matrix can be performed in parallel and the necessary data arranged in storage elements 22 by processor 82 or controller 70, or both, for example by writing two multi-bit values into each storage element 22, by storing a single bit of each of two multi-bit values into each storage element 22, for example storage elements 22 of memory components 40 having product storage capacitors 16 connected in common, or by storing a first multi-bit value into multiple storage elements 22 and a different bit of a second multi-bit value into each of multiple storage elements 22, for example in memory components 40 having iterative multi-bit product circuits compute engines 30. Each different bit stored in a different memory component 40 can be stored in a same location in storage element 22 of the memory component 40 so that a single operation performed by different compute engines 30 in different memory components 40 can perform the same operation using different bits of a multi-bit value, e.g., the second multi-bit value.

According to embodiments of the present disclosure, a multi-processor computer system 80 comprises a compact in-memory computer 10 comprising memory components 40 and a processor 82 spatially and logically separate, independent, and external from compact in-memory computer 10 connected to compact in-memory computer 10. Each memory component 40 can comprise a compute engine 30 and storage element 22. Storage elements 22 can comprise one bit cell 22 or multiple bit cells 22. Compute engines 30 can comprise a single bit multiplier 14 and a product storage capacitor 16 or an iterative bit multiplier 14 and a product storage capacitor 16. Bit products can be accumulated in an accumulator storage circuit 17 or capacitor 17. Capacitors 16 or 17 can be electrically connected together, for example each through a switch circuit 18. Compute engine 30 can be operable to read data (e.g., bits or multiple bits of a digital binary value) and process data (e.g., by performing bit multiplications) from only storage element 22 of memory component 40. In some embodiments, compute engine 30 can write data to storage element 22 of memory component 40. Processor 82 can be operable to write data to each storage element 22 in compact in-memory computer 10 and, in some embodiments, read data from each storage element 22 in compact in-memory computer 10. The data can be multi-bit values in a matrix that are multiplied to provide a matrix multiplication performed in parallel, either in a two-dimensional array, in rows, or in columns of an array. Thus, storage elements 22 can be responsive to compact in-memory-computer addresses in a compact in-memory-computer address range and processor 82 is operable to write data to memory components 40 at the compact in-memory-computer addresses. In some embodiments processor 82 is operable to read data from storage elements 22 at compact in-memory-computer addresses in a compact in-memory-computer address range.

In some embodiments, data is written into storage elements 22 of compact in-memory computer 10 by controlling word lines 26 as address lines and bit lines 24 as data lines in a memory write operation. The memory write operation can include controlling one or more control bits, for example bits that provide memory-select switch control (e.g., to turn memory-select switch on or off). In some embodiments, compute engines 30 can provide two or more different operations and the control bits can indicate or select an operation of the two or more different operations, e.g., an operate command so that processor 82 provides the operate command together with data as part of a storage element 22 write operation that writes the data into storage elements 22 of memory components 40.

In some embodiments, controller 70 comprises one or more analog-to-digital converters 36, for example connected to each row or column of memory components 40 or connected to a one or more multiplexers 32 connected to each row or column of memory components 40 so that the analog-to-digital converters 36 can convert data (e.g., analog values such as charges or voltages) for multiple rows or columns of memory components 40 at a time or select and convert data using multiplexer(s) 32. Controller 70 can comprise one or more accumulation circuits, either digital or analog, scaling circuits such as binary shift circuits (e.g., place value connections), for example in shift and accumulate circuits.

In some embodiments, compute engines 30 can provide analog computation, for example by incorporating full or partial operational amplifier (Op Amp) circuits or differential amplifiers, fully differential amplifiers, and isolation amplifiers that provide arithmetic functions including summations and multiplications. Compute engines 30 can provide multiply-accumulate functions, dot-product functions, and convolution functions, among other functions. In embodiments, compute engines 30 can comprise one or more of analog elements, analog current sources, analog storage elements (e.g., capacitors such as product storage circuit 16 and accumulator storage circuit 17), multiplexing mechanisms (e.g., multiplexer(s) 32), and analog-to-digital converter 36 (e.g., as shown in FIG. 3D). Compute engine 30 can be operable to accumulate states (e.g., values or bits) of a controllable selection of bit cell(s) 20 in storage element 22. Compute engine 30 can perform analog computation (e.g., to accumulate values) and, optionally, convert the result of analog computation on bit-cell data (or bit-cell data directly) to digital values that can be accessed by or transmitted to other compute engines 30 or controller 70, for example replacing the functionality of analog-to-digital converter 36 in controller 70, as shown with the dashed element outline.

In embodiments of the present disclosure, analog-to-digital converters 36 can have a relatively low-precision, for example when applied to accumulated values, either accumulated iteratively (e.g., as in FIG. 7) or in parallel (e.g., as in FIG. 9). If a reduced precision is acceptable, for example an eight-bit value rather than a nine-bit value for an accumulated value of 512 bits (data stored in 512 parallel-connected bit cells 20), a reduced-precision analog-to-digital converter 36 can be used to save power and circuit area and to increase speed. This design can also be applied to iteratively accumulated products. In particular, if it is known that many of the bit products have a high probability of equaling zero, fewer bits can be used to store the accumulation of the bit products, with no loss in precision, or at least a reduced likelihood of precision loss. Such a design can be much more energy efficient, potentially by an order of magnitude, and produce acceptable results.

In embodiments where it is important to maintain precision, separate analog-to-digital converters 36 with reduced precision can be applied to single values or partial accumulations and the results then added digitally (e.g., as in FIG. 11) to provide an accumulated value with full precision. For example, if 256 bits are accumulated, an eight-bit analog-to-digital converter 36 is required to convert the accumulation without loss of precision. Alternatively, four six-bit analog-to-digital converters 36 can convert a corresponding four partial values (of 64 bits each) and the four values summed digitally to provide the eight-bit accumulated value. This design reduces the size and power and increases the speed of the analog-to-digital converters 36 at the expense of additional digital adders.

More generally, an external device or system (e.g., a process or cpu or controller 70) can write to or read from any subset of bit cell(s) 20 of storage elements 22 in any memory component 40 of compact in-memory computer 10, so that storage elements 22 (and bit cells 20) are memory mapped into a memory space of the external device or system. Compute engines 30 of memory components 40 are operable to compute or process data stored in bit cells 20 of storage elements 22 of memory components 40.

Embodiments of the present disclosure provide high-speed operation at a relatively low power for compact in-memory computer and compact in-memory architecture arrays of memory components 40 suitable for matrix multiplication. In some embodiments, operations are analog and operate at a much lower power than can be the case for digital computations. For example, bit products can be summed using capacitors, for example providing averaging functions or iterative accumulation providing averaging and scaling with very little power use or time delay. Bit capacitors 16 (and 17) can be very small, to reduce the area of bit capacitor 16 in an integrated circuit embodiment and the charge necessary to store or read a value in capacitor 16. Digital, binary scaling operations can be achieved simply through interconnections providing relative multiplication by powers of two to adding circuits with no additional power cost.

Operating power for storage elements 22, bit-multiply circuits 14, and analog storage circuits 16, 17 can have a voltage no greater than one V (e.g., no greater 500 mV, no greater than 100 mV, no greater than 50 mV, or no greater than 10 mV) that operates at a much lower voltage and power than digital circuits providing similar functions. The multiply circuit can comprises serially connected switches comprising pairs of MOS transistors, for example operating in a low-voltage, low-power regime that consumes less power than a conventional digital MOS circuit. Hence, embodiments of the present disclosure can perform many (e.g., billions) of bit-product-and-accumulation operations at a time with a very low power to provide high-speed, efficient parallel operation for matrix multiplication computing tasks, among other computing tasks.

Embodiments of the present disclosure are not limited to the specific examples illustrated in the figures and described herein. Skilled designers will readily appreciate that various implementations of analog and digital circuits can be employed to implement the operations described and such implementations are included in embodiments of the present disclosure.

Embodiments of the present disclosure can be used in neural networks, pattern-matching computers, or machine-learning computers and provide efficient and timely processing with reduced power and hardware requirements. Such embodiments can comprise a computing accelerator, e.g., a neural network accelerator, a pattern-matching accelerator, a machine learning accelerator, or an artificial intelligence computation accelerator designed for static or dynamic processing workloads.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific elements, or where processes and methods are described as having, including, or comprising specific steps, it is contemplated that, additionally, there are apparatus and systems of the disclosed technology that consist essentially of, or consist of, the recited elements, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the following claims.

### PARTS LIST

O output
P product
10 compact in-memory computer architecture/compact in-memory computer
14 bit multiplier/bit-multiply circuit
15 serial switch circuit
16 capacitor/analog storage circuit/product storage circuit
17 capacitor/analog storage circuit/accumulator storage circuit
18 switch/switch circuit
20 bit cell
21C bit column
21R bit row
22 storage element
24 bit line
25 external bit line
26 word line
28 word store
30 compute engine (CE)
32 multiplexer
33 demultiplexer
36 analog-to-digital converter
38 digital shift-and-accumulate (SAC) circuit
40 memory component
50 switch/transistor
60 MEMSEL (memory-select) switch
62 accumulation switch
64 output switch
70 controller
80 multi-processor computer system
82 processor
100 provide memory component step
110 close MEMSEL step
120 write bit into bit cell step
130 open MEMSEL step
140 CE read bit from bit cell step/compute (process) data step
150 CE process bit step
160 write step
200 select row step
210 provide data step
220 enable word line step
230 read computed data step
305 set B_{M} bit selection step
306 set B_{M} bit count M to zero step
310 clear capacitors step
315 select B bit_{M} step
320 set switch to multiplication mode step
325 bit multiply step
330 set switch to average mode step
331 set accumulation mode step
335 accumulate step
340 analog-to-digital conversion
345 shift accumulate
350 test all B bits multiplied step
355 set B bit count M to M+1 step
360 store product step

1. A compact in-memory computer architecture, comprising:
memory components arranged in rows and columns, each memory component comprising a bit cell and a compute engine connected to the bit cell, wherein the bit cell is operable to store a bit and the compute engine is operable to process the bit;
bit lines, each bit line connected to a respective row of memory components, the bit lines operable to provide a bit to each memory component in the row of memory components; and
word lines, each word line connected to a respective column of memory components, the word lines operable to enable each memory component in the column of memory components to write a bit into each memory component in the column of memory components.

2. The compact in-memory computer architecture of claim 1, wherein each memory component is connected to a bit line external to the memory component through a memory select (MEMSEL) switch that is operable to connect the memory component to the bit line internal to the memory component or isolate the memory component from the bit line external to the memory component.

3. The compact in-memory computer architecture of claim 2, wherein the memory select (MEMSEL) switch of each memory component is controlled in common.

4. The compact in-memory computer architecture of claim 1, wherein each memory component comprises multiple bit cells connected to the compute engine and each bit cell of the multiple bit cells is connected to a common bit line and to a different word line.

5. The compact in-memory computer architecture of claim 4, wherein each bit cell in a memory component is connected directly to the compute engine.

6. The compact in-memory computer architecture of claim 1, comprising a controller for controlling the memory components.

7. The compact in-memory computer architecture of claim 1, comprising a substrate and wherein each memory component is spatially disposed on or over a different portion of the substrate and adjacent to another memory component.

8. The compact in-memory computer architecture of claim 7, wherein the compute engine of each memory component is disposed spatially adjacent to the bit cell or bit cells of the memory component.

9. The compact in-memory computer architecture of claim 7, wherein at least one of the compute engines in the memory components is spatially disposed between the bit cell or bit cells of the memory component and the bit cell or bit cells of the adjacent memory component.

10. The compact in-memory computer architecture of claim 7, wherein each compute engine of a memory component is connected to the compute engine of an adjacent memory component.

11. The compact in-memory computer architecture of claim 1, wherein for each memory component the compute engine is connected to the bit cell with the corresponding bit line.

12. The compact in-memory computer architecture of claim 1, wherein the compute engine comprises a it multiplier for multiplying bits stored in the bit cells to calculate a product and a product storage circuit that is or comprises a capacitor for storing the product.

13. A method of operating the compact in-memory computer architecture of claim 7, comprising:
using the controller to provide a bit on each bit line;
using the controller to enable the word line of a column of memory components to store the bit into the bit cell of each memory component in the column of memory components; and
using the compute engine of each memory component in the column of memory components to process the stored bit.

14. The method of claim 13, wherein each memory component is connected to a corresponding bit line through a memory select (MEMSEL) switch and comprising using the controller (i) to turn the MEMSEL switch on before using the controller to provide the bit on each bit line and (ii) to turn the MEMSEL switch off after using the controller to provide the bit on each bit line before using the compute engine of each memory component in the column of memory components to process the stored bit.

15. The method of claim 13, comprising: (i) multiplying multiple bits of a first multi-bit value by a bit of a second multi-bit value in parallel; multiplying multiple bits of a first multi-bit value by a bit of a second multi-bit value in parallel; (iii) multiplying multiple bits of a first multi-bit value by a bit of a second multi-bit value in parallel; (iv) multiplying all of the bits of a first multi-bit value by a bit of a second multi-bit value in parallel; (v) multiplying multiple bits of a first multi-bit value by multiple bits of a second multi-bit value in parallel; (vi) multiplying all of the bits of a first multi-bit value by all of the bits of a second multi-bit value in parallel; (vii) storing bit products in capacitors and summing the bit products by connecting the capacitors in parallel; or (viii) iteratively summing and scaling bit products in an accumulating capacitor.
